(19) United States
(12) Patent Application Publication
(10) Pub. No.: US 2025/0125222 A1
(43) Pub. Date: Apr. 17, 2025

(54) HIGH PERFORMANCE MEMORY DEVICE

(71) Applicant: Taiwan Semiconductor Manufacturing Company, Ltd., Hsinchu (TW)

(72) Inventors: Ping-Wei Wang, Hsin-Chu (TW); Feng-Ming Chang, Hsinchu County (TW); Jui-Lin Chen, Taipei City (TW)

(21) Appl. No.: 18/411,382

(22) Filed: Jan. 12, 2024

Related U.S. Application Data
(60) Provisional application No. 63/590,279, filed on Oct. 13, 2023.

(51) Int. Cl. H01L 23/48; H01L 29/06; H01L 29/423; H01L 29/775; H01L 29/786; H10B 10/00

(52) U.S. Cl. CPC H01L 23/481; H10B 10/125; H10D 30/43; H10D 30/6735; H10D 30/6757; H10D 62/121

(57) ABSTRACT

A semiconductor structure according to the present disclosure includes a first memory cell that includes a first pull-down transistor and a first pull-up transistor sharing a first gate structure extending along a first direction, a second pull-down transistor and a second pull-up transistor sharing a second gate structure extending along the first direction, a first pass-gate transistor having a third gate structure spaced apart but aligned with the second gate structure along the first direction, and a second pass-gate transistor having a fourth gate structure spaced apart but aligned with the first gate structure along the first direction, a frontside interconnect structure disposed over the first memory device, a backside interconnect structure disposed below the first memory device. A source of the second pull-down transistor is electrically coupled to the backside interconnect structure by way of a first backside contact via.

### PRIORITY DATA

This application claims priority to U.S. Provisional Patent Application Ser. No. 63/590,279, filed Oct. 13, 2023, entitled “MEMORY DEVICES WITH FRONTSIDE AND BACKSIDE CONTACTS”, the entirety of which is incorporated herein by reference.

### BACKGROUND

The electronics industry has experienced an ever-increasing demand for smaller and faster electronic devices which are simultaneously able to support a greater number of increasingly complex and sophisticated functions. Accordingly, there is a continuing trend in the semiconductor industry to manufacture low-cost, high-performance, and low-power integrated circuits (ICs). Thus far, these goals have been achieved in large part by scaling down semiconductor IC dimensions (e.g., minimum feature size) and thereby improving production efficiency and lowering associated costs. However, such scaling has also introduced increased complexity to the semiconductor manufacturing process. Thus, the realization of continued advances in semiconductor ICs and devices calls for similar advances in semiconductor manufacturing processes and technology.

Static random access memory (“SRAM”) generally refers to any memory or storage that can retain stored data only when power is applied. As integrated circuit (IC) technologies progress towards smaller technology nodes, multi-gate structures, such as fin-like field effect transistors (FinFETs) or gate-all-around (GAA) transistors, are integrated into SRAM cells to enhance performance. As dimensions of SRAM cells continue to shrink, the contact structures that functionally interconnect the transistors in SRAM cells present additional challenges in reduction of resistance (R) and capacitance (C).

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion.

FIG. 1 is a circuit schematic of an SRAM cell according to various aspects of the present disclosure.

FIG. 2 is a top view of an SRAM cell, according to various aspects of the present disclosure.

FIG. 3 is a fragmentary top view of a frontside interconnect structure of an SRAM quad-cell, according to various aspects of the present disclosure.

FIG. 4 is fragmentary cross-sectional view along cross section A-A′ in FIG. 3, according to various aspects of the present disclosure.

FIG. 5 is a fragmentary top view of a backside interconnect structure of an SRAM quad-cell, according to various aspects of the present disclosure.

FIG. 6 is fragmentary cross-sectional view along cross section B-B′ in FIG. 5, according to various aspects of the present disclosure.

FIG. 7 is fragmentary cross-sectional view along cross section C-C′ in FIG. 5, according to various aspects of the present disclosure.

FIG. 8 is a fragmentary top view of a frontside interconnect structure of an SRAM quad-cell, according to various aspects of the present disclosure.

FIG. 9 is fragmentary cross-sectional view along cross section B-B′ in FIG. 8, according to various aspects of the present disclosure.

FIG. 10 is fragmentary cross-sectional view along cross section B-B′ in FIG. 8, according to various aspects of the present disclosure.

FIG. 11 is a fragmentary top view of a frontside interconnect structure of an SRAM quad-cell, according to various aspects of the present disclosure.

FIG. 12 is a fragmentary top view of a backside interconnect structure of an SRAM quad-cell, according to various aspects of the present disclosure.

FIG. 13 is fragmentary cross-sectional view along cross section D-D′ in FIG. 12, according to various aspects of the present disclosure.

FIG. 14 is fragmentary cross-sectional view along cross section E-E′ in FIG. 12, according to various aspects of the present disclosure.

FIG. 15 is a fragmentary top view of a backside interconnect structure of an SRAM quad-cell, according to various aspects of the present disclosure.

FIG. 16 is a fragmentary top view of a backside interconnect structure of an SRAM quad-cell, according to various aspects of the present disclosure.

FIG. 17 is a block diagram of an SRAM array, according to various aspects of the present disclosure.

FIGS. 18-21 are top layout view of the SRAM array in FIG. 17, according to various aspects of the present disclosure.

FIG. 22 is a block diagram of an SRAM array that includes power tap edge cells, according to various aspects of the present disclosure.

FIGS. 23-27 are top layout view of an SRAM array that includes a power tap edge cell, according to various aspects of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +/−15% by one of ordinary skill in the art. When describing aspects of a transistor, source/drain region(s) may refer to a source or a drain, individually or collectively, dependent upon the context.

Static Random Access Memory (SRAM) is a semiconductor memory that retains data in a static form as long as the memory has power. Compared to dynamic RAM (DRAM), SRAM is faster and more reliable and does not need to be refreshed. SRAM is widely used in many applications, such as a computer's cache memory and as part of the random access memory of digital-to-analog converter on a video card. As integrated circuit (IC) technologies progress towards smaller technology nodes, multi-gate structures, such as fin-like field effect transistors (FinFETs) or gate-all-around (GAA) transistors, are integrated into SRAM cells to enhance performance. The shrinkage in dimensions presents stress on electrical routing. When only a frontside interconnect structure is present, contact via and metal lines are tightly spaced and the frontside connections to various transistor nodes in an SRAM cell may exhibit high resistance. The tight spacing and the high contact resistance may lead to high resistance and capacitance, which may lead to low drive current and slow speed.

The present disclosure provides SRAM devices that include not only a frontside interconnect but also a backside interconnect to improve performance of SRAM devices. In one embodiment, sources of pull-down transistors are coupled to a backside ground rail by way of backside contacts to improve pull-down current while sources of pass-gate transistors are not coupled to the backside ground rail. This arrangement improves a beta ratio and an alpha ratio of the SRAM device. In another embodiment, backside contacts to sources of pull-down transistors of adjacent SRAM cells may merge to reduce contact resistance. In still another embodiment, frontside butted contacts are replaced with backside butted contact to provide cross-latching. This provides space savings from removal of the frontside butted contacts. In yet another embodiment, filled-through-via (FTVs) are placed in power tap areas along edges of an SRAM array. The FTV provides additional front-to-back electrical routes in addition to or in place of the backside contacts.

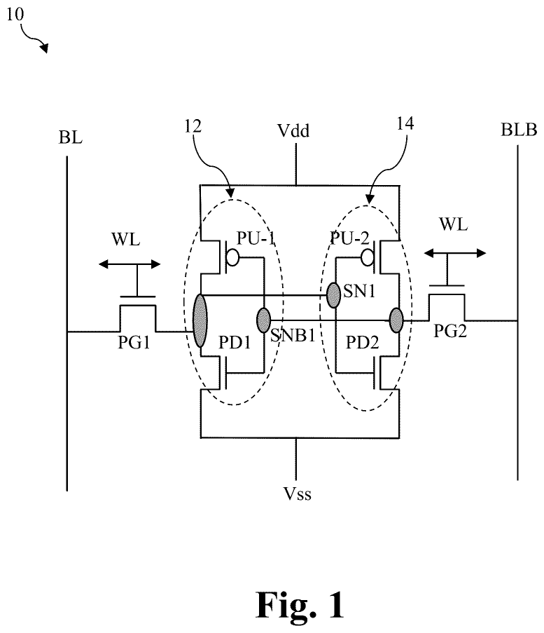

FIG. 1 illustrates an example type of memory device in which transistors such as planar transistors, FinFET transistors, or gate-all-around (GAA) transistors may be implemented. In that regard, FIG. 1 illustrates the circuit schematic of an example SRAM device, for example, as a single-port SRAM cell (e.g., 1-bit SRAM cell) 10. The single-port SRAM cell 10 includes first and second pass-gate transistors PG1 and PG2, first and second pull-up transistors PU1 and PU2, and first and second pull-down transistors PD1 and PD-2. The gates of the first and second pass-gate transistors PG1 and PG2 are electrically coupled to word-line (WL) that determines whether the SRAM cell 10 is selected or not. In the SRAM cell 10, a memory bit (e.g., a latch or a flip-flop) is formed of the first and second pull-up transistors PU1 and PU2 and the first and second pull-down transistors PD1 and PD2 to store a bit of data. The complementary values of the bit are stored in a first storage node SN1 and a first complementary storage node SNB1. The stored bit can be written into, or read from, the SRAM cell 10 through Bit-line (BL) and Bit-Line Bar (BLB). In this arrangement, the BL and BLB may carry complementary bit-line signals. The SRAM cell 10 is powered through a positive power supply voltage Vdd and is also connected to a ground potential Vss.

The SRAM cell 10 includes a first inverter 12 formed of the first pull-up transistor PU1 and the first pull-down transistor PD1 as well as a second inverter 14 formed of the second pull-up transistor PU2 and the second pull-down transistor PD2. As shown in FIG. 1, drains of the first pull-up transistor PU1 and the first pull-down transistor PD1 are coupled together and drains of the second pull-up transistor PU2 and the second pull-down transistor PD2 are coupled together. The first inverter 12 and the second inverter 14 are coupled between the positive supply voltage Vdd and the ground potential Vss. As shown in FIG. 1, the first inverter 12 and the second inverter 14 are cross-coupled. That is, the first inverter 12 has an input coupled to the output of the second inverter 14. Likewise, the second inverter 14 has an input coupled to the output of the first inverter 12. The output of the first inverter 12 is referred to as the first storage node SN1. Likewise, the output of the second inverter 14 is referred to as the first complementary storage node SNB1. In a normal operating mode, the first storage node SN1 is in the opposite logic state (logic high or logic low) as the first complementary storage node SNB1. By employing the two cross-coupled inverters, the SRAM cell 10 can hold the data using a latched structure so that the stored data will not be lost without applying a refresh cycle as long as power is supplied through Vdd.

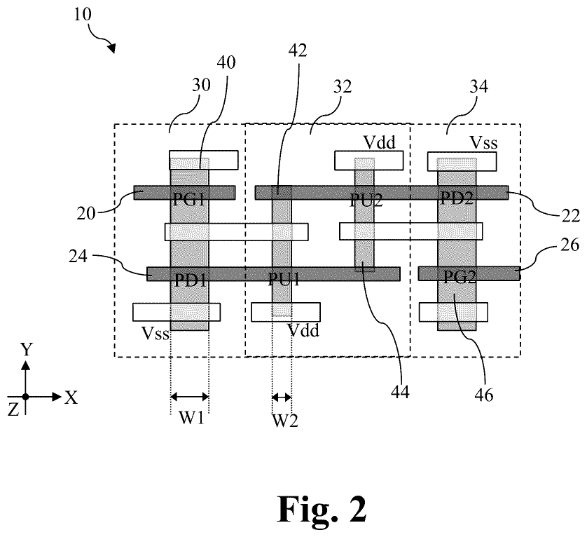

Referring now to FIG. 2, shown therein is an example layout of the SRAM cell 10 in FIG. 1. Like the SRAM cell 10 in FIG. 1, the layout in FIG. 2 includes six (6) transistors functioning as the first pass-gate transistor PG1, the second pass-gate transistor PG2, the first pull-up transistor PU1, the second pull-up transistor PU2, the first pull-down transistor PD1, and the second pull down transistor PD2. In some implementations represented in FIG. 2, the SRAM cell 10 may be formed over an n-type well 32 (or N well 32) sandwiched between two p-type wells 30 and 34 (or P wells 30 and 34). The N well 32 and P wells 30, 34 are formed over a substrate. In some embodiments, as shown in FIG. 2, the first pass-gate transistor PG1, the first pull-down transistor PD1, the second pull-down transistor PD2, and the second pass-gate transistor PG2 may be formed over the P wells 30 and 34; and the first pull-up transistor PU1 and the second pull-up transistor PU2 are formed in the N well 32. In these embodiments, the first pass-gate transistor PG1, the first pull-down transistor PD1, the second pull-down transistor PD2, and the second pass-gate transistor PG2 are n-type GAA transistors; and the first pull-up transistor PU1 and the second pull-up transistor PU2 are p-type GAA transistors.

In some embodiments, the SRAM cell 10 includes four fin-shaped vertical stacks—a first fin-shaped vertical stack 40, a second fin-shaped vertical stack 42, a third fin-shaped vertical stack 44, and a fourth fin-shaped vertical stack 46. The first fin-shaped vertical stack 40 is formed over the P well 30 and forms the channel regions of the first pass-gate transistor PG1 and the first pull-down transistor PD1. The second fin-shaped vertical stack 42 and third fin-shaped vertical stack 44 are formed over the N well 32 and form the channel regions of the first pull-up transistor PU1 and the second pull-up transistor PU2, respectively. The fourth fin-shaped vertical stack 46 is formed over the P well 34 and forms the channel regions of the second pull-down transistor PD2 and the second pass-gate transistor PG2. Each of the first, second, third, and fourth fin-shaped vertical stacks 40, 42, 44, and 46 may include about two (2) to about ten (10) channel members. In some embodiments, each of the first, second, third, and fourth fin-shaped vertical stacks 40, 42, 44, and 46 includes 4 channel members. Each of the first, second, third, and fourth fin-shaped vertical stacks 40, 42, 44, and 46 may be referred to as an active region.

In some instances, the fin-shaped vertical stacks may be formed by depositing or epitaxially growing alternating layers of two different semiconductor materials, patterning the alternating layers to form fin-shaped structures, and selectively removing layers formed of one of the two semiconductor materials. For example, alternating layers of epitaxially grown silicon (Si) and silicon germanium (SiGe) can be formed on a substrate. The substrate may be a silicon (Si) substrate. The alternating layers may then be patterned to form fin-shaped structures that include stacks of interleaved Si strips and SiGe stripes. In processes to form a channel region of a transistor in a SRAM cell, the channel region of the fin-shaped structures may undergo different etching processes to selectively remove the SiGe strips, releasing silicon layers as suspended silicon channel members. The channel members may assume different shapes and dimensions and may be referred to as nanostructure, nanowires, or nanosheets. These fin-shaped structures are separated by an isolation feature, such as a shallow trench isolation (STI) feature. In some implementations, each of the fin-shaped vertical stacks may include a top portion formed from the alternating layers and a base portion formed from the substrate. The base portions of the fin-shaped vertical stacks have a shape of a fin and may be referred to as fin structures. The base portions of the fin-shaped vertical stacks may be substantially buried in the isolation feature and top ends of the base portions of the fin-shaped vertical stacks may be level with a top surface of the isolation feature. The top portions of the fin-shaped vertical stacks extend from and rise above the isolation feature.

Reference is still made to FIG. 2. The channel members in the first fin-shaped vertical stack 40 form channel regions of the first pass-gate transistor PG1 and the first pull-down transistor PD1. The channel members in the second fin-shaped vertical stack 42 form channel regions of the first pull-up transistor PU1. The channel members in the third fin-shaped vertical stack 44 form channel regions of the second pull-up transistor PU2. The channel members in the fourth fin-shaped vertical stack 46 form channel regions of the second pull-down transistor PD2 and the second pass-gate transistor PG2. In the depicted embodiments, the first fin-shaped vertical stack 40 and the fourth fin-shaped vertical stack 46 are used to form n-type GAA transistors and the second fin-shaped vertical stack 42 and the third fin-shaped vertical stack 44 are used to form p-type GAA transistors. In the embodiments illustrated in FIG. 2, the first pass-gate transistor PG1, the first pull-down transistor PD1, the second pass-gate transistor PG2, the second pull-down transistor PD2 are n-type GAA transistors, and the first pull-up transistor PU1 and the second pull-up transistor PU-2) are p-type GAA transistors. In FIG. 2, each of the first fin-shaped vertical stack 40 and fourth fin-shaped vertical stack 46 has a first width W1 along the X direction and each of the second fin-shaped vertical stack 42 and the third fin-shaped vertical stack 44 has a second width W2 along the X direction. In some embodiments, in order to achieve better read/write performance, the n-type GAA transistors have greater channel widths than the p-type GAA transistors. That is, the first width W1 may be greater than the second width W2. In some instances, a ratio of the first width W1 to the second width W2 (W1/W2) is between about 1 and about 5, including between about 1.1 and about 3.0.

As illustrated in FIG. 2, a channel of the first pass-gate transistor PG1 is controlled by a gate structure 20, channels of the first pull-down transistor PD1 and the first pull-up transistor PU1 are controlled by a gate structure 24, channels of the second pull-down transistor PD2 and the second pull-up transistor PU2 are controlled by a gate structure 22, and a channel of the second pass-gate transistor PG2 is controlled by a gate structure 26. As the gate structures 20 and 22 are segmented from a single gate structure, they are aligned lengthwise along the X direction. As the gate structures 24 and 26 are segmented from a single gate structure, they are aligned lengthwise along the X direction. The first fin-shaped vertical stack 40, the second fin-shaped vertical stack 42, the third fin-shaped vertical stack 44, and the fourth fin-shaped vertical stack 46 extend lengthwise along the Y direction, perpendicular to the X direction. In circuit and physical design, the SRAM cell 10 shown in FIG. 2 may serve as a repeating unit in an SRAM array. For ease of signal routing, adjacent SRAM cells 10 in an SRAM array may be mirror images of one another along their borders.

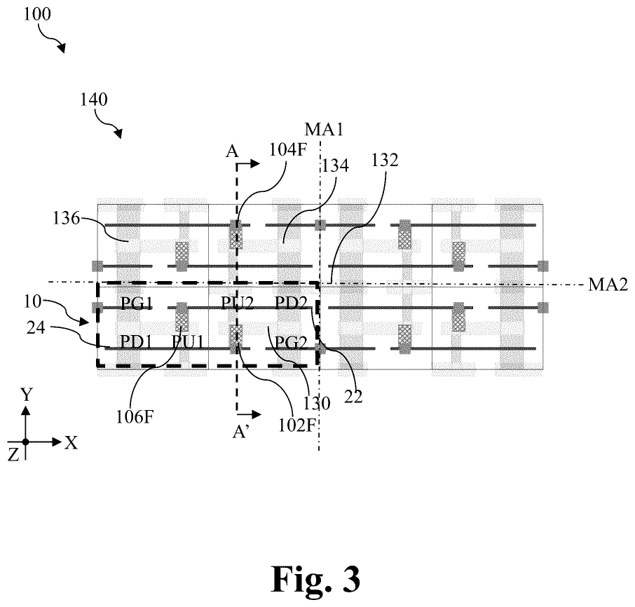

FIGS. 3-7 illustrate various aspects of an example embodiment where sources of the first pull-down transistor PD1 and the second pull-down transistor PD2 are electrically coupled to a backside ground rail by way of a backside contact. With respect to this example embodiment, FIG. 3 illustrates a frontside interconnect layer 140 of a quad-cell 100 that includes 4 SRAM cells 10. An SRAM cell 10 is shown in FIG. 3 as a dotted rectangular box. For illustration purposes, FIG. 3 also includes a first mirror axis MA1, which extends along the Y direction and a second mirror axis MA2, which extends along the X direction. It can be seen that the SRAM cell across the first mirror axis MA1 from the SRAM cell 10 is a mirror image of the SRAM cell 10. Similarly, the SRAM cell across the second mirror axis MA2 from the SRAM cell is a mirror image of the SRAM cell 10. The mirror imaging configuration allows merging of the pull-up transistors, the pull-down transistors, and pass-gate transistors for efficient routing and electrical connection. The frontside interconnect layer 140 in FIG. 3 include butted contacts, such as a first frontside butted contact 102F, a second frontside butted contact 104F, and a third frontside butted contact 106F. The first frontside butted contact 102F couples a gate structure 24 of the first pull-up transistor PU1 to a source of the second pull-up transistor PU2. In the SRAM cell above the SRAM cell 10, the frontside butted contact 104F also couples a gate structure of the first pull-up transistor PU1 to a source of the second pull-up transistor PU2. The third frontside butted contact 106F couples the gate structure 22 of the second pull-up transistor PU2 to the source of the first pull-up transistor PU1. FIG. 3 also shows a first common contact 130 that couples together drains of the second pull-up transistor PU2 and the second pull-down transistor PD2, a second common contact 132 that couples together sources of two adjacent pull-down transistors, a third common contact 134 couples together drains of a pull-up transistor and a pull-down transistor, and fourth common contact 136 that couples together sources of a pull-up transistor and a pull-down transistor.

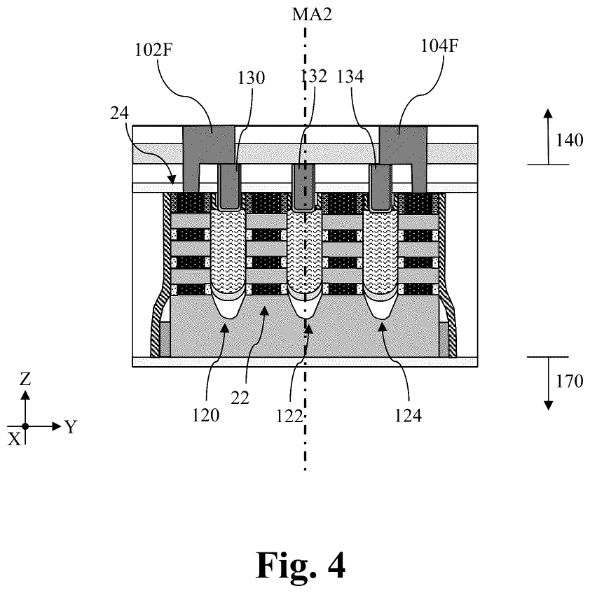

FIG. 4 illustrates a fragmentary cross-sectional view along cross section A-A′ in FIG. 3. As shown in FIG. 4, cross section A-A′ cuts through the gate structure 24, the gate structure 22, a gate structure that is a mirror image of the gate structure 22 (with respect to the second mirror axis MA2), and a gate structure that is a mirror image of the gate structure 24 (with respect to the second mirror axis MA2), the first common contact 130, the second common contact 132, and the third common contact 134, the first frontside butted contact 102F, the second frontside butted contact 104F, source 120 of the second pull-up transistor PU2, drain 122 of the second pull-up transistor PU2, and source 124 of the pull-up transistor in the SRAM cell over the SRAM cell 10. FIG. 4 also illustrates that the frontside interconnect layer 140 is disposed above the transistors and the backside interconnect layer 170 is disposed below the transistors.

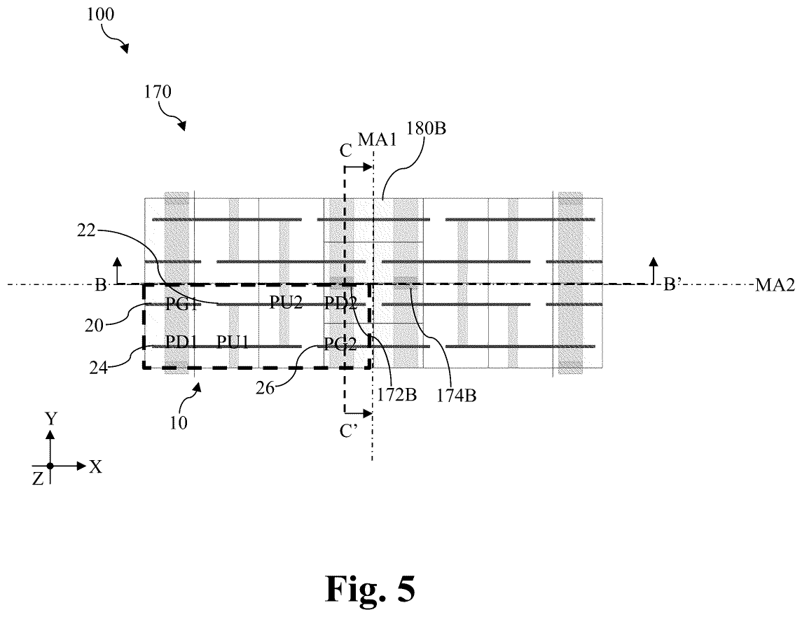

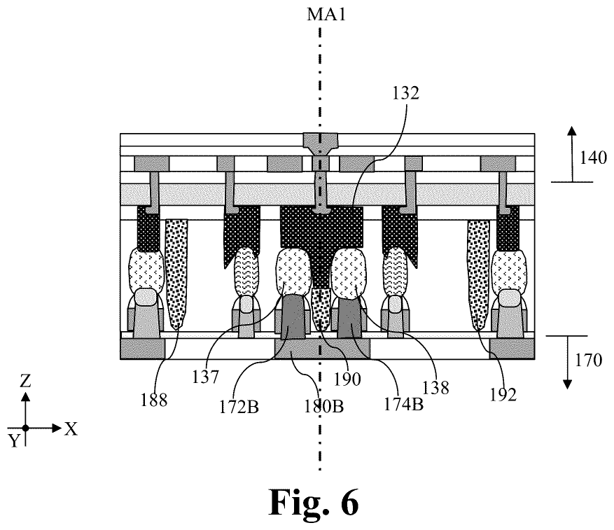

FIG. 5 illustrates the backside interconnect layer 170 below the quad-cell 100. FIG. 5 illustrates a first backside source contact 172B and a second backside source contact 174B. The first backside source contact 172B and the second backside source contact 174B connects source of pull-down transistors (including the second pull-down transistor PD2) to a backside ground rail 180B. As shown in FIG. 5, the first backside source contact 172B and the second backside source contact 174B directly land on the backside ground rail 180B. It is noted that sources of the first pull-up transistor PU1, the second pull-up transistor PU2, the first pass-gate transistor PG1, and the second pass-gate transistor PG2 are not coupled to any conductive features in the backside interconnect layer 170 by way of any counterpart of the first backside source contact 172B or the second backside source contact 174B. FIG. 6 illustrates a fragmentary cross-sectional view of the quad-cell 100 along cross section B-B′ in FIG. 5. The mirror image placement of the SRAM cells in the quad-cell 100 allows a source 137 of the second pull-down transistor PD2 to be placed next to a source 138 of a pull-down transistor in an SRAM cell over the SRAM cell 10. In some embodiments represented in FIG. 6, the sources 137 and 138 are coupled to the Vss via not only through the second common contact 132 but also through the first backside source contact 172B and the second backside source contact 174B. The additional electrical grounding provided by the first backside source contact 172B and the second backside source contact 174B enables a higher saturation current for the second pull-down transistor PD2. Because the sources of the pass-gate transistors are not coupled to additional backside contacts, saturation currents of the pass-gate transistors are kept low. The greater saturation current of the pull-down transistors help keep a beta (β) ratio of the SRAM cell 10 greater than 1, which allows the SRAM cell 10 have good read stability. The lower saturation current of the pass-gate transistors help keep an alpha (α) ratio of the SRAM cell high, which allows the SRAM cell 10 to have good writability. The fragmentary cross-sectional view in FIG. 6 also illustrates a first gate cut feature 188, a second gate cut feature 190 and a third gate cut feature 192. Referring to FIGS. 5 and 6, the first gate cut feature 188 isolates the gate structures 20 and 22. The second gate cut feature 190 isolates the gate structure 22 from a gate structure in a mirror image SRAM cell across the first mirror axis MA1. The third gate cut feature 192 is a mirror image of the first gate cut feature 188 and serves a similar function. The first, second and third gate cut features 188, 190 and 192 may include silicon nitride, silicon oxide, silicon oxynitride, silicon oxycarbonitride, silicon oxycarbide, silicon carbonitride, or a combination thereof. The first backside source contact 172B and the second backside source contact 174B may include tungsten (W).

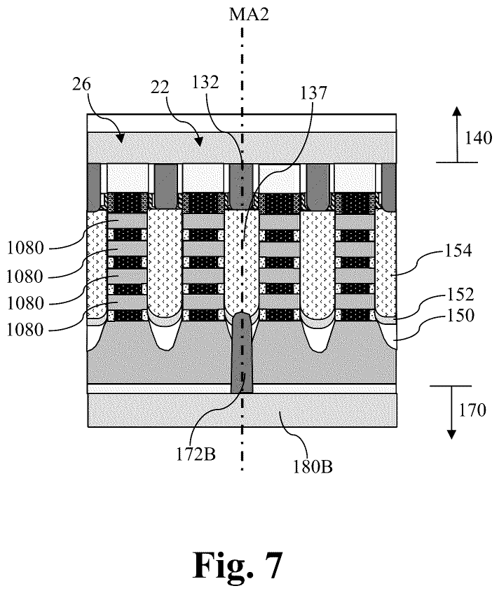

FIG. 7 illustrate a fragmentary cross-sectional view of the quad-cell 100 along cross-section C-C′ in FIG. 5. As shown in FIG. 5, cross section C-C′ cuts through the SRAM cell 10 and a mirror image SRAM cell across the second mirror axis MA2. Referring to FIG. 7, cross section C-C′ cuts through gate structures 26 and 22 in the SRAM cell 10 as well as the counterpart gate structures in the mirror image SRAM cell across the second mirror axis MA2. FIG. 7 shows that the first backside source contact 172B extends from a top surface of the backside ground rail 180B to electrically couple to the source 137 of the second pull-down transistor PD2. The source 137 of the second pull-down transistor PD2 is also electrically coupled to the second common contact 132. As described before, this arrangement provide additional current paths between the source of the second pull-down transistor PD2 and the ground rail.

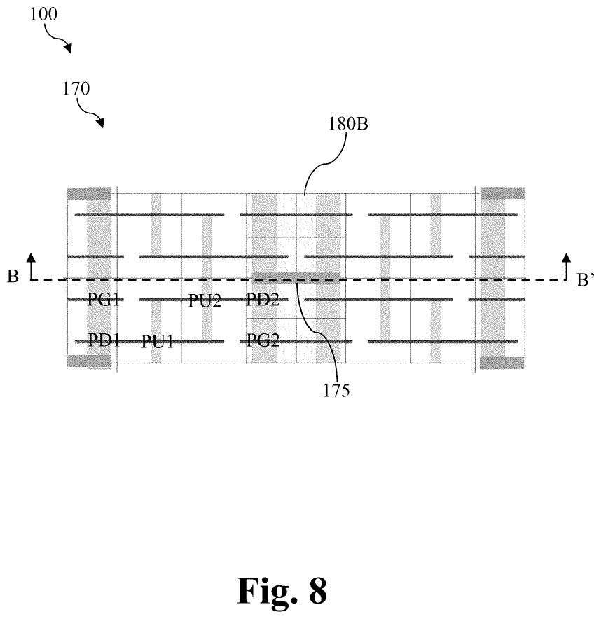

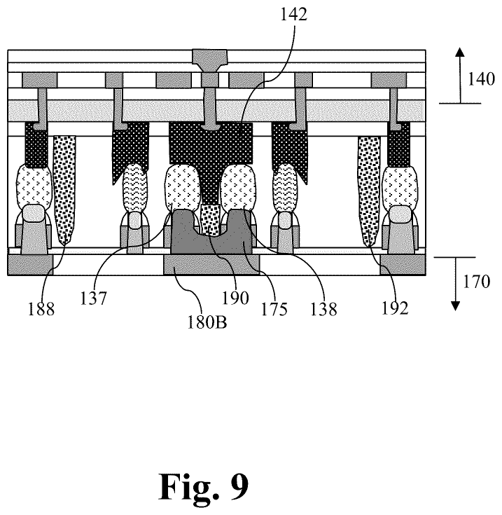

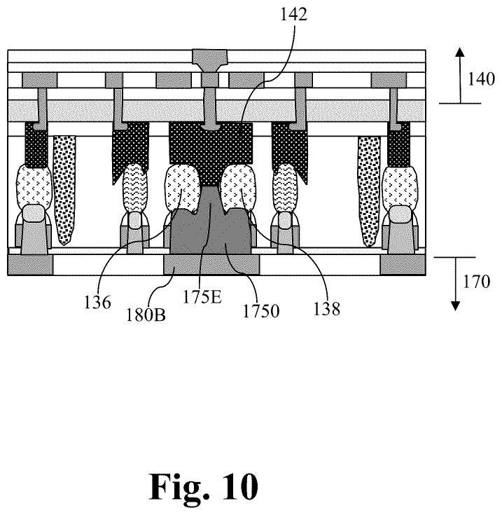

FIGS. 8-10 illustrate various aspects of an example embodiment where two adjacent backside contact vias may merge to form a backside slot contact so as to reduce contact resistance. Like FIG. 5, FIG. 8 also illustrates the backside interconnect layer 170 below the quad-cell 100. Different from FIG. 5, FIG. 8 illustrates a backside slot contact 175. The backside slot contact 175 is structurally similar to a first backside source contact 172B and a second backside source contact 174B that are partially merged. As shown in FIG. 8, a portion of the backside slot contact 175 spans over sources 137 and 138 of two adjacent pull-down transistors of two adjacent SRAM cells. FIG. 9 illustrates a fragmentary cross-sectional view of the quad-cell 100 along cross section B-B′ in FIG. 8. In some embodiments represented in FIG. 9, the backside slot contact 175 not only spans completely below the sources 137 and 138 of two adjacent pull-down transistors but also extends through a portion of the second gate cut feature 190. As shown in FIG. 9, the backside slot contact 175 has an enlarged interface with the underlying backside ground rail 180B. Because a cross-sectional area of the conductive path is inversely related to the resistance, the enlarged interface provided by the backside slot contact 175 may effectively reduce the contact resistance with the backside ground rail 180B. In some embodiments represented in FIG. 10, because the etch process for forming the backside slot contact opening may etch the second gate cut feature 190 at a greater rate, a wrap-around backside slot contact 1750 may be formed. The wrap-around backside slot contact 1750 includes an extension 175E that extends between the source 137 and the source 138. Compared to the backside slot contact 175 in FIG. 9, the wrap-around backside slot contact 1750 may have a larger contact area with the sources 137 and 138. The backside slot contact 175 and the wrap-around backside slot contact 1750 may include tungsten (W).

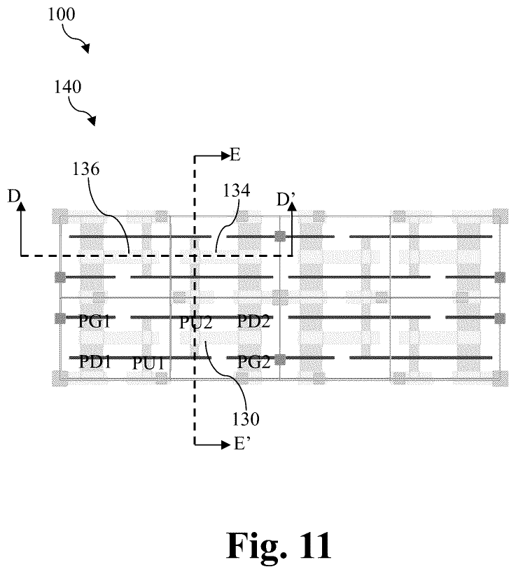

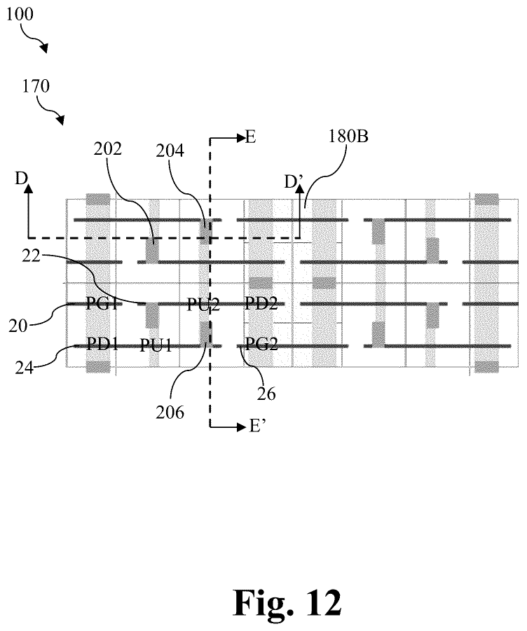

FIG. 11-14 illustrate various aspects of an example embodiment where frontside butted contacts, such as the first frontside butted contact 102F, the second frontside butted contact 104F, and the third frontside butted contact 106F shown in FIGS. 3 and 4, are replaced with backside butted contacts. Functionally, the frontside butted contacts described above in conjunction with FIGS. 3 and 4 adequately perform the intended electrical connections to allow the quad-cell 100 to operate properly. However, as shown in FIG. 4, the first frontside butted contact 102F, the second frontside butted contact 104F, and the third frontside butted contact 106F may unavoidably take up precious routing space in the first metal layer (M0) over the FEOL structure. In some embodiments, as illustrated in FIG. 11, the frontside butted contacts are removed from the frontside interconnect layer 140. To replace the frontside butted contacts, backside butted contacts, such as a first backside butted contact 202, a second backside butted contact 204, and a third backside butted contact 206, are formed in the backside interconnect layer 170 shown in FIG. 12. In some implementations, a vertical projection area of a backside butted contact may substantially overlap with a vertical projection area of a frontside butted contact it replaces. For example, a vertical projection area of the second frontside butted contact 104F may substantially overlap with a vertical projection area of the second backside butted contact 204. In some implementations, the first backside butted contact 202, the second backside butted contact 204, and the third backside butted contact 206 may include tungsten (W).

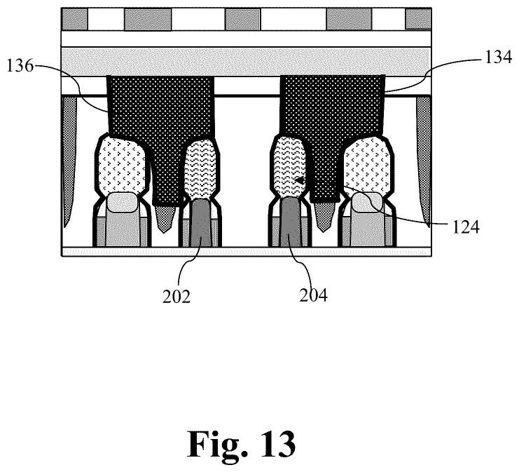

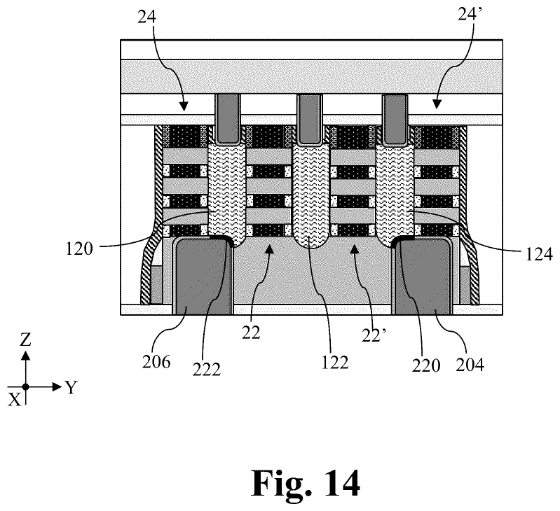

Fragmentary cross-sectional views along cross section D-D′ and cross section E-E′ in FIG. 12 show how the first backside butted contact 202, the second backside butted contact 204, and the third backside butted contact 206 are situated to couple to different features. FIG. 13 is fragmentary cross-sectional view along cross section D-D′ and FIG. 14 is fragmentary cross-sectional view along cross section E-E′. Referring first to FIG. 13, cross section D-D′ cut through the third common contact 134, the fourth common contact 136, the first backside butted contact 202, and the second backside butted contact 204. As shown in FIG. 13, each of the first backside butted contact 202 and the second backside butted contact 204 engages a source of a pull-up transistor, such as the source 124. Referring now to FIG. 14, cross section E-E′ cuts through the source 120 of the second pull-up transistor PU2, the drain 122 of the second pull-up transistor PU2, the source 124 of the pull-up transistor in the SRAM cell adjacent the SRAM cell 10, gate structures 22 and 24, gate structures 22′ and 24′ in the SRAM cell adjacent the SRAM cell 10, the second backside butted contact 204, and the third backside butted contact 206. As shown in FIG. 14, the third backside butted contact 206 are electrically coupled to the gate structure 24 and the source 120 and the second backside butted contact 204 are electrically couple to the gate structure 24′ and the source 124. It can be seen that along the Y direction, each of the second backside butted contact 204 and the third backside butted contact 206 has a width to engage a gate structure (24 or 24′ in FIG. 14) and an adjacent source (120 or 124 in FIG. 14). In some embodiments, the second backside butted contact 204 interfaces the source 124 by way of a first silicide layer 220 and the third backside butted contact 206 interfaces the source 120 by way of a second silicide layer 222. In some embodiments, the first silicide layer 220 and the second silicide layer 222 may include a metal silicide, such as titanium silicide (TiSi), tungsten silicide (WSi), nickel silicide (NiSi), or cobalt silicide (CoSi).

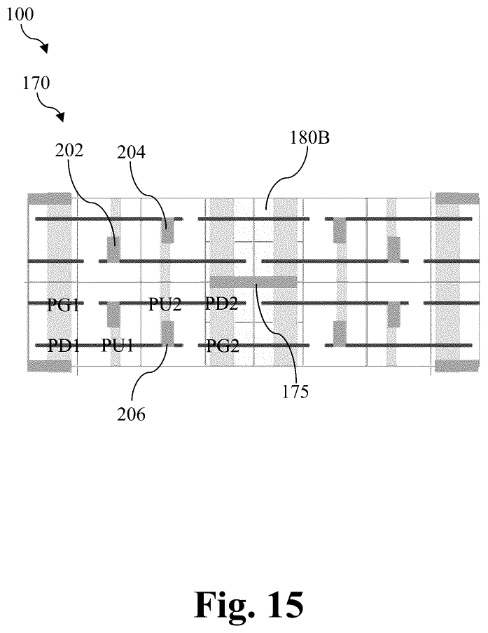

In some embodiments represented in FIG. 15, the backside slot contact 175 illustrated in FIG. 9 (or the wrap-around backside slot contact 1750 illustrated in FIG. 10) may be implemented in the qual-cell 100 along with the backside butted contacts illustrated in FIGS. 12-14. FIG. 15 is a fragmentary top view of a backside interconnect layer 170 of the quad-cell 100. The backside interconnect layer 170 in FIG. 15 includes the backside slot contact 175, the first backside butted contact 202, the second backside butted contact 204, and the third backside butted contact 206.

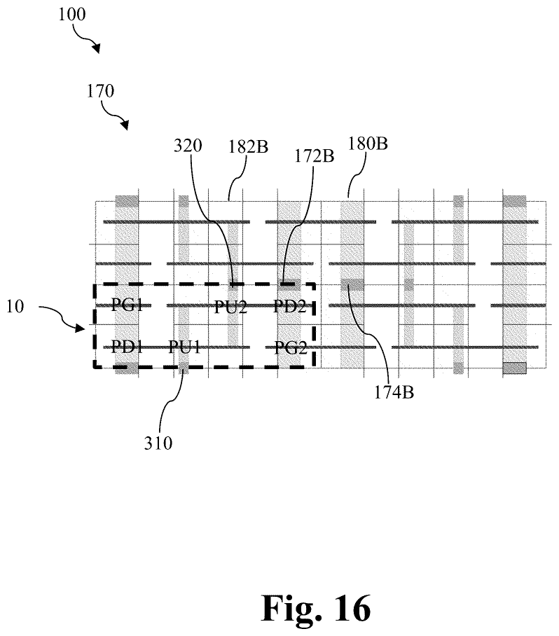

In some embodiments represented in FIG. 16, the quad-cell 100 also includes a first backside drain contact 310 and a second backside drain contact 320 in addition to the first backside source contact 172B and the second backside source contact 174B. With respect to the SRAM cell 10, the first backside drain contact 310 is electrically coupled to a bottom surface of the drain of the first pull-up transistor PU1 and the second backside drain contact 320 is electrically coupled to a bottom surface of the drain of the second pull-up transistor PU2. Instead of being coupled to the backside ground rail 180B, both the first backside drain contact 310 and the second backside drain contact 320 are coupled to a backside supply rail 182B. While the backside ground rail 180B is coupled to the ground potential Vss, the backside supply rail 182B is coupled to the positive supply voltage Vdd. It can be seen that backside slot contacts (or backside wrap-around slot contacts) or the backside butted contacts may also be implemented along with the backside drain contacts.

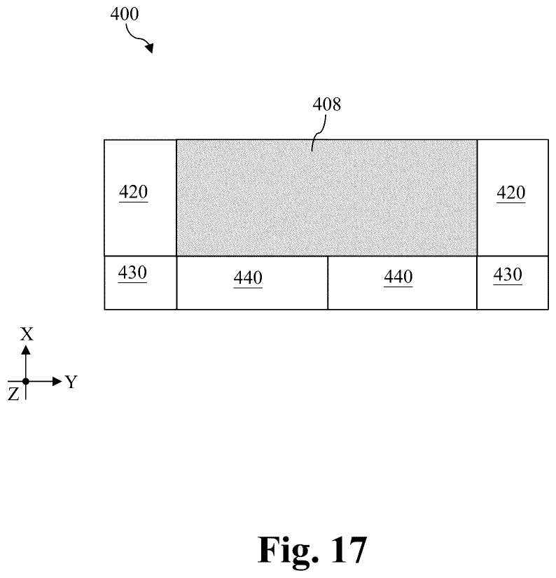

FIG. 17 is a block diagram of a first SRAM array 408 in a first memory device 400. The first SRAM array 408 may include a plurality of the SRAM cell 10 described above, each of which is arranged as a mirror image of a neighboring SRAM cell 10. In the first SRAM array 408, gate structures extend lengthwise along the X direction and the fin-shaped vertical stacks (or active regions) extend lengthwise along the Y direction. In some embodiments, the first SRAM array 408 is disposed between two input/output (I/O) cells 420 along the Y direction. Two word line drivers 440 are disposed along an edge of the first SRAM array 408. The first memory device 400 also includes two controllers 430. Each of the two controllers 430 engages one I/O cell 420 and one word line driver 440. Due to implementation of backside source contacts (e.g., the first backside source contact 172B and the second backside source contact 174B), backside slot contact (e.g., the backside slot contact 175 or wrap-around backside slot contact 1750), backside butted contacts (e.g., the first backside butted contact 202, the second backside butted contact 204, or the third backside butted contact 206), or a combination thereof, the first SRAM array 408 does not include any well tap cells to provide ground potential (Vss) or positive supply potential (Vdd) to the well regions.

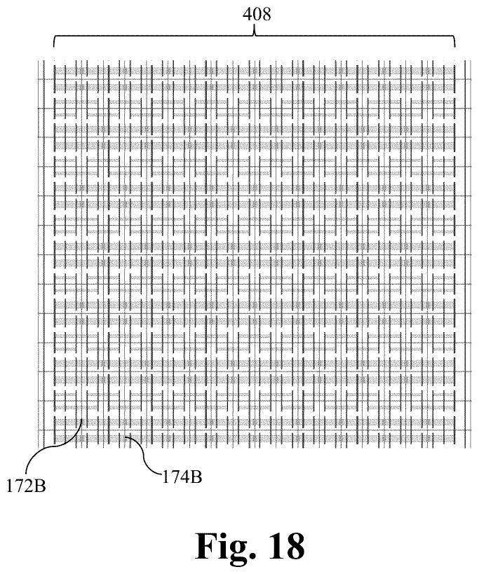

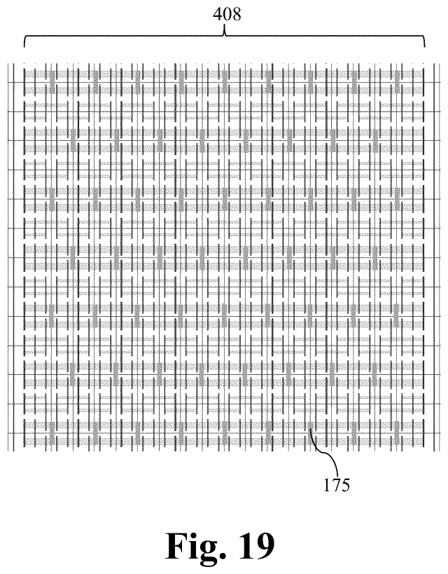

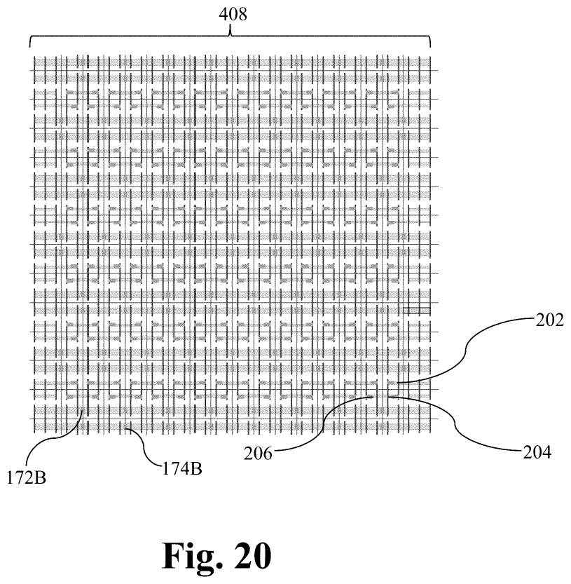

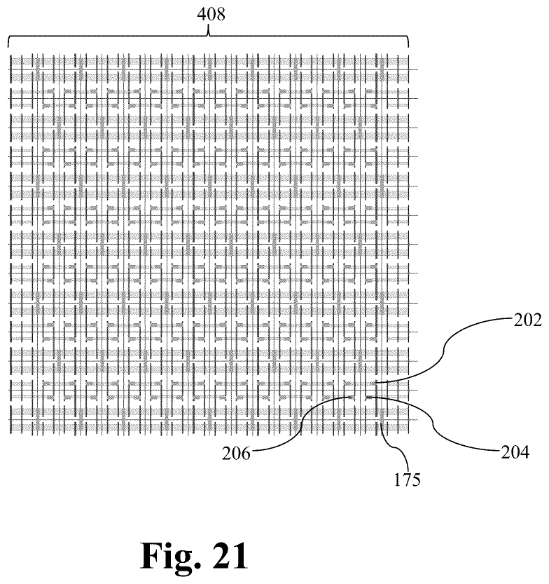

In some embodiments represented in FIG. 18, the first SRAM array 408 includes backside source contacts (e.g., the first backside source contact 172B and the second backside source contact 174B) to couple sources of pull-down transistors to backside ground rails (e.g., the backside ground rail 180B). In some embodiments presented in FIG. 19, the first SRAM array 408 includes backside slot contacts (e.g., the backside slot contact 175 or wrap-around backside slot contact 1750) to couple sources of pull-down transistors to backside ground rails (e.g., the backside ground rail 180B). In some embodiments represented in FIG. 20, the first SRAM array 408 includes backside source contacts (e.g., the first backside source contact 172B and the second backside source contact 174B) and backside butted contacts (e.g., the first backside butted contact 202, the second backside butted contact 204, or the third backside butted contact 206). In some embodiments represented in FIG. 21, the first SRAM array 408 includes backside butted contacts (e.g., the first backside butted contact 202, the second backside butted contact 204, or the third backside butted contact 206) and backside slot contacts (e.g., the backside slot contact 175 or wrap-around backside slot contact 1750).

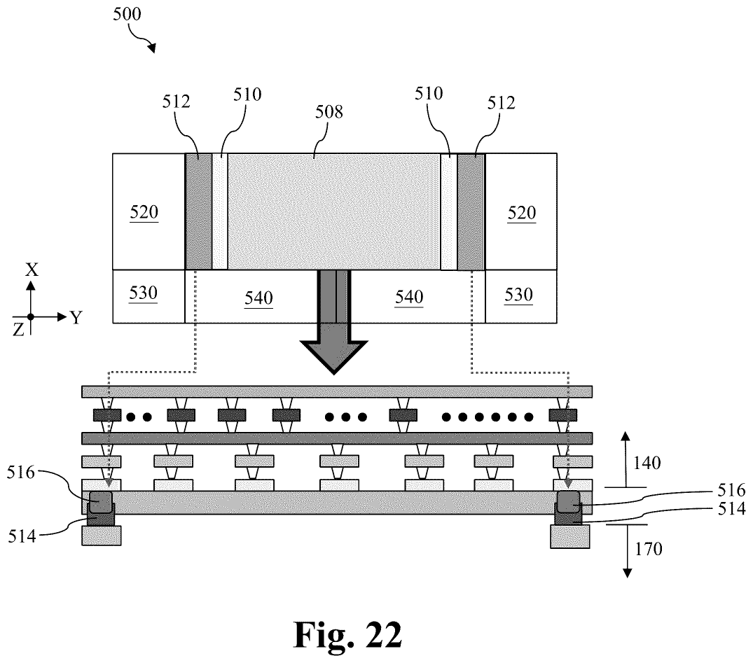

FIG. 22 is a block diagram of a second SRAM array 508 in a second memory device 500. The second SRAM array 508 may include a plurality of the SRAM cell 10 described above, each of which is arranged as a mirror image of a neighboring SRAM cell 10. In the second SRAM array 508, gate structures extend lengthwise along the X direction and the fin-shaped vertical stacks (or active regions) extend lengthwise along the Y direction. In some embodiments, the second SRAM array 508 is disposed between two input/output (I/O) cells 520 along the Y direction. Two word line drivers 540 are disposed along an edge of the second SRAM array 508. The second memory device 500 also includes two controllers 530. Each of the two controllers 530 engages one I/O cell 520 and one word line driver 540. Different from the first memory device 400, the second memory device 500 also includes two power tap edge cells 512 disposed along the interfaces with the I/O cells 520. In some embodiments, each of the two power tap edge cells 512 is spaced apart from the second SRAM array 508 by a tapless buffer edge 510. In some embodiments, each of the power tap edge cells 512 includes an array of feedthrough vias (FTVs) 514. Coupled with a frontside contact 516, each of the FTV 514 provides electrical routing between the frontside interconnect layer 140 and the backside interconnect layer 170. The FTVs 514 provide additional front-to-back electrical routing in place of or in addition to the backside source contacts, backside drain contacts, backside slot contacts, or backside butted contacts. In some embodiments, the FTV 514 includes tungsten (W) and the frontside contact 516 includes aluminum (Al), copper (Cu), cobalt (Co), nickel (Ni), titanium (Ti), ruthenium (Ru), or tungsten (W).

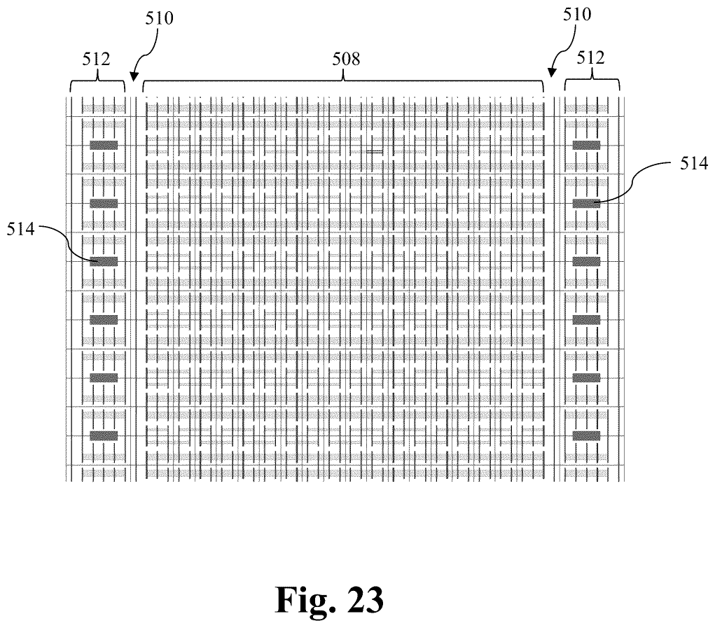

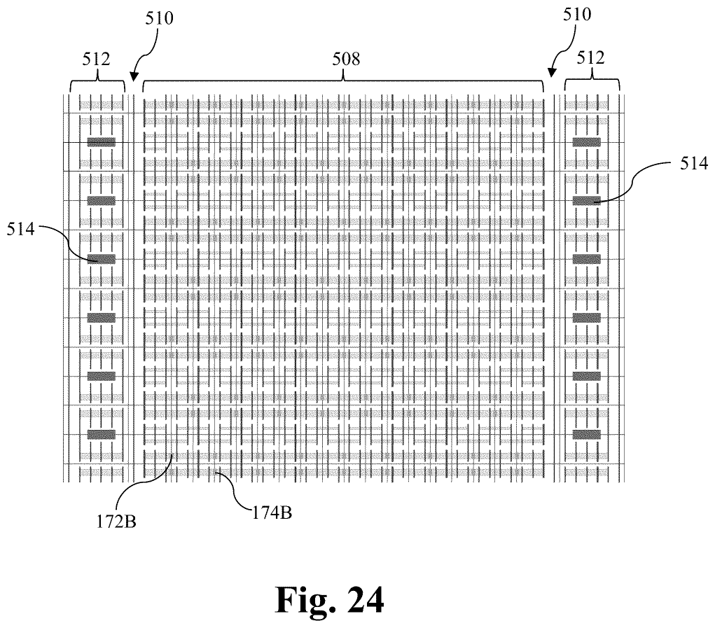

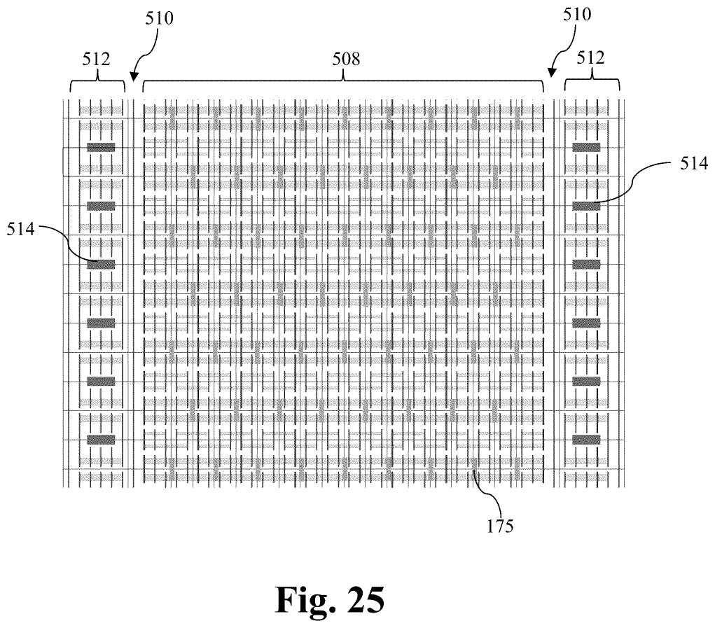

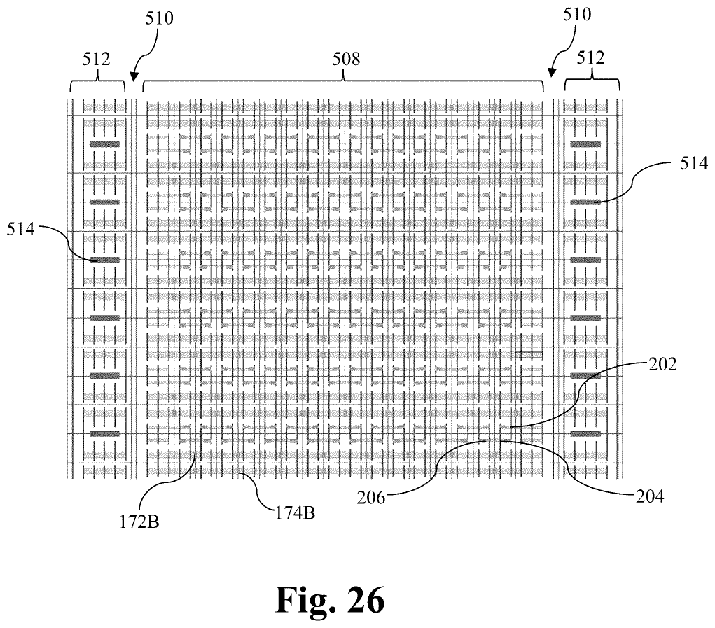

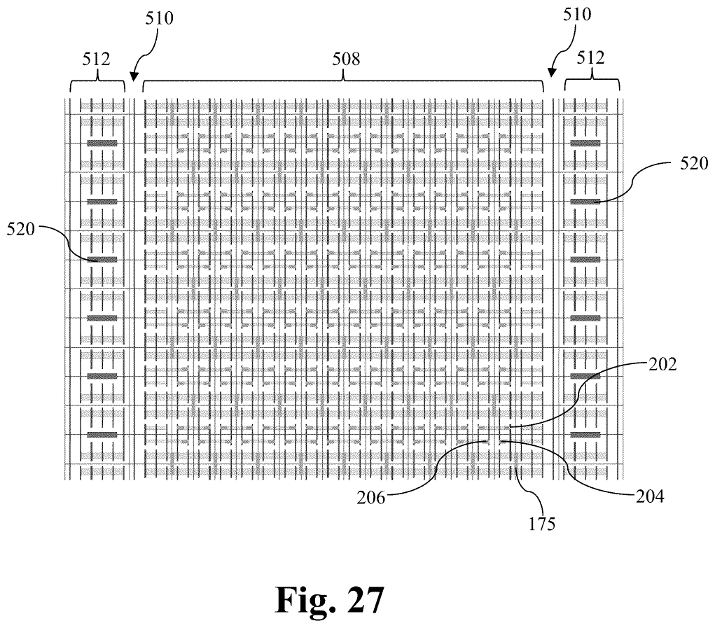

In some embodiments presented in FIG. 23, the second SRAM array 508 do not have any of the backside source contacts, backside drain contacts, backside slot contacts, or backside butted contacts. The FTVs 514 may be used to couple frontside positive supply potential or frontside ground potential to backside positive supply rails or backside ground rails. In some embodiments represented in FIG. 24, the second SRAM array 508 includes backside source contacts (e.g., the first backside source contact 172B and the second backside source contact 174B) to couple sources of pull-down transistors to backside ground rails (e.g., the backside ground rail 180B). The FTVs 514 may be used to couple frontside routing to backside positive supply rail or backside ground rail. In some embodiments represented in FIG. 25, the second SRAM array 508 includes backside slot contacts (e.g., the backside slot contact 175 or wrap-around backside slot contact 1750). In some embodiments presented in FIG. 26, the second SRAM array 508 includes backside source contacts (e.g., the first backside source contact 172B and the second backside source contact 174B) and backside butted contacts (e.g., the first backside butted contact 202, the second backside butted contact 204, or the third backside butted contact 206). In some embodiments presented in FIG. 27, the second SRAM array 508 includes backside source contacts (e.g., the first backside source contact 172B and the second backside source contact 174B) to couple sources of pull-down transistors to backside ground rails (e.g., the backside ground rail 180B) and backside slot contacts (e.g., the backside slot contact 175 or wrap-around backside slot contact 1750) to couple sources of pull-down transistors to backside ground rails (e.g., the backside ground rail 180B).

In one example aspect, the present disclosure provides a semiconductor structure. The semiconductor structure includes a first memory cell that includes a first pull-down transistor and a first pull-up transistor sharing a first gate structure extending along a first direction, a second pull-down transistor and a second pull-up transistor sharing a second gate structure extending along the first direction, a first pass-gate transistor having a third gate structure spaced apart but aligned with the second gate structure along the first direction, and a second pass-gate transistor having a fourth gate structure spaced apart but aligned with the first gate structure along the first direction, a frontside interconnect structure disposed over the first memory cell, and a backside interconnect structure disposed below the first memory cell. A source of the second pull-down transistor is electrically coupled to the frontside interconnect structure by way of a first source/drain contact and the source of the second pull-down transistor is electrically coupled to the backside interconnect structure by way of a first backside contact via.

In some embodiments, an active region of the first pull-down transistor and an active region of the first pass-gate transistor are aligned along a second direction perpendicular to the first direction and an active region of the second pull-down transistor and an active region of the second pass-gate transistor are aligned along the second direction. In some implementations, each of the active regions of the first pull-down transistor, the first pass-gate transistor, the second pull-down transistor, and the second pass-gate transistor includes four nanostructures stacked one over another. In some embodiments, the first pull-down transistor has a first channel width and the first pull-up transistor has a second channel width smaller than the first channel width. In some embodiments, the semiconductor structure further includes a first backside butted contact physically contacting the first gate structure and a source of the second pull-up transistor. In some embodiments, the semiconductor structure further includes a second backside butted contact physically contacting the second gate structure and a source of the first pull-up transistor. In some embodiments, the semiconductor structure further includes a second memory cell that includes a third pull-down transistor and a third pull-up transistor sharing a third gate structure extending along the first direction, a fourth pull-down transistor and a fourth pull-up transistor sharing a fourth gate structure extending along the first direction, a third pass-gate transistor having a fifth gate structure spaced apart but aligned with the fourth gate structure along the first direction, and a fourth pass-gate transistor having a sixth gate structure spaced apart but aligned with the third gate structure along the first direction. The second memory cell is a mirror image of the first memory cell with respect to second direction such that the second gate structure is aligned with the third gate structure and that the first gate structure is aligned with the fifth gate structure along the first direction. The frontside interconnect structure is disposed over the second memory cell. The backside interconnect structure is disposed below the second memory cell. A source of the third pull-down transistor is electrically coupled to the backside interconnect structure by way of a second backside contact via. In some implementations, the first backside contact via and the second backside contact via land directly on a backside power rail in the backside interconnect structure. In some embodiments, the first backside contact via and the second backside contact via merge before they land directly on the backside power rail.

Another aspect of the present disclosure pertains to a memory structure. The memory structure includes a first memory cell that includes a first active region, a second active region, a third active region, and a fourth active region extending in parallel along a first direction, a first gate structure extending lengthwise along a second direction perpendicular to the first direction, the first gate structure engaging the first active region and the second active region to form a first pull-down transistor and a first pull-up transistor, respectively, and a second gate structure extending lengthwise along the second direction, the second gate structure engaging the third active region and the fourth active region to form a second pull-up transistor and a second pull-down transistor, respectively, a frontside interconnect structure disposed over the first memory cell, and a backside interconnect structure disposed below the first memory cell. A source of the second pull-down transistor is electrically coupled to the frontside interconnect structure by way of a first source/drain contact. The source of the second pull-down transistor is electrically coupled to the backside interconnect structure by way of a first backside contact via.

In some embodiments, the first memory cell further includes a third gate structure extending lengthwise along the second direction and engaging the first active region to form a first pass-gate transistor, and a fourth gate structure extending lengthwise along the second direction and engaging the fourth active region to form a second pass-gate transistor. In some implementations, the third gate structure is aligned with and spaced apart from the second gate structure along the second direction and the fourth gate structure is aligned with and spaced apart from the first gate structure along the second direction. In some instances, the first active region and the fourth active region include a first width along the second direction, the second active region and the third active region include a second width along the second direction, and the second width is smaller than the first width. In some implementations, the memory structure further includes a second memory cell that includes a fifth active region, a sixth active region, a seventh active region, and an eighth active region extending in parallel along the first direction, a third gate structure extending lengthwise along the second direction to engage the fifth active region and the sixth active region to form a third pull-down transistor and a third pull-up transistor, respectively, and a fourth gate structure extending lengthwise along the second direction to engage the seventh active region and the eighth active region to form a fourth pull-up transistor and a fourth pull-down transistor, respectively, the frontside interconnect structure disposed over the second memory cell, the backside interconnect structure disposed below the second memory cell. A source of the third pull-down transistor is electrically coupled to the backside interconnect structure by way of a second backside contact via. In some instances, the fourth active region and the fifth active region are spaced apart by an isolation feature. In some instances, the first backside contact via and the second backside contact via merge below the isolation feature.

Yet another aspect of the present disclosure pertains to a semiconductor device. The semiconductor device includes a first pull-down transistor and a first pull-up transistor sharing a first gate structure extending along a direction, a second pull-down transistor and a second pull-up transistor sharing a second gate structure extending along the direction, a first pass-gate transistor having a third gate structure spaced apart but aligned with the second gate structure along the direction, a second pass-gate transistor having a fourth gate structure spaced apart but aligned with the first gate structure along the direction, a first backside butted contact physically contacting a bottom surface of the first gate structure and a bottom surface of a source of the second pull-up transistor, and a second backside butted contact physically contacting the second gate structure and a source of the first pull-up transistor.

In some embodiments, the first pull-down transistor includes a plurality of first nanostructures, the first gate structure wraps around each of the plurality of first nanostructures, the first pass-gate transistor includes a plurality of second nanostructures, the third gate structure wraps around each of the plurality of second nanostructures, the plurality of first nanostructures include a first width along the direction, the plurality of second nanostructures include a second width along the direction, and the first width is greater than the second width. In some embodiments, the plurality of first nanostructures include four (4) first nanostructures stacked one over another. In some instances, the semiconductor device further includes a frontside interconnect structure disposed over the first pull-down transistor, the first pull-up transistor, the second pull-down transistor, the second pull-up transistor, the first pass-gate transistor, and the second pass-gate transistor, and a backside interconnect structure disposed below the first pull-down transistor, the first pull-up transistor, the second pull-down transistor, the second pull-up transistor, the first pass-gate transistor, and the second pass-gate transistor. A source of the second pull-down transistor is electrically coupled to the frontside interconnect structure by way of a frontside source/drain contact and the source of the second pull-down transistor is electrically coupled to the backside interconnect structure by way of a backside contact via.

The foregoing has outlined features of several embodiments. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions and alterations herein without departing from the spirit and scope of the present disclosure.

What is claimed is:

1. A semiconductor structure, comprising:
a first memory cell that includes:
a first pull-down transistor and a first pull-up transistor sharing a first gate structure extending along a first direction,
a second pull-down transistor and a second pull-up transistor sharing a second gate structure extending along the first direction,
a first pass-gate transistor having a third gate structure spaced apart but aligned with the second gate structure along the first direction, and
a second pass-gate transistor having a fourth gate structure spaced apart but aligned with the first gate structure along the first direction;
a frontside interconnect structure disposed over the first memory cell; and
a backside interconnect structure disposed below the first memory cell,
wherein a source of the second pull-down transistor is electrically coupled to the frontside interconnect structure by way of a first source/drain contact,
wherein the source of the second pull-down transistor is electrically coupled to the backside interconnect structure by way of a first backside contact via.

2. The semiconductor structure of claim 1,
wherein an active region of the first pull-down transistor and an active region of the first pass-gate transistor are aligned along a second direction perpendicular to the first direction,
wherein an active region of the second pull-down transistor and an active region of the second pass-gate transistor are aligned along the second direction.

3. The semiconductor structure of claim 2, wherein each of the active regions of the first pull-down transistor, the first pass-gate transistor, the second pull-down transistor, and the second pass-gate transistor comprises four nanostructures stacked one over another.

4. The semiconductor structure of claim 1,
wherein the first pull-down transistor has a first channel width,
wherein the first pull-up transistor has a second channel width smaller than the first channel width.

5. The semiconductor structure of claim 1, further comprising:
a first backside butted contact physically contacting the first gate structure and a source of the second pull-up transistor.

6. The semiconductor structure of claim 5, further comprising:
a second backside butted contact physically contacting the second gate structure and a source of the first pull-up transistor.

7. The semiconductor structure of claim 1, further comprising:
a second memory cell that includes:
a third pull-down transistor and a third pull-up transistor sharing a third gate structure extending along the first direction,
a fourth pull-down transistor and a fourth pull-up transistor sharing a fourth gate structure extending along the first direction,
a third pass-gate transistor having a fifth gate structure spaced apart but aligned with the fourth gate structure along the first direction, and
a fourth pass-gate transistor having a sixth gate structure spaced apart but aligned with the third gate structure along the first direction,
wherein the second memory cell is a mirror image of the first memory cell with respect to second direction such that the second gate structure is aligned with the third gate structure and that the first gate structure is aligned with the fifth gate structure along the first direction,
wherein the frontside interconnect structure is disposed over the second memory cell,
wherein the backside interconnect structure is disposed below the second memory cell,
wherein a source of the third pull-down transistor is electrically coupled to the backside interconnect structure by way of a second backside contact via.

8. The semiconductor structure of claim 7, wherein the first backside contact via and the second backside contact via land directly on a backside power rail in the backside interconnect structure.

9. The semiconductor structure of claim 8, wherein the first backside contact via and the second backside contact via merge before they land directly on the backside power rail.

10. A memory structure, comprising:
a first memory cell comprising:
a first active region, a second active region, a third active region, and a fourth active region extending in parallel along a first direction,
a first gate structure extending lengthwise along a second direction perpendicular to the first direction, the first gate structure engaging the first active region and the second active region to form a first pull-down transistor and a first pull-up transistor, respectively, and
a second gate structure extending lengthwise along the second direction, the second gate structure engaging the third active region and the fourth active region to form a second pull-up transistor and a second pull-down transistor, respectively;
a frontside interconnect structure disposed over the first memory cell; and
a backside interconnect structure disposed below the first memory cell,
wherein a source of the second pull-down transistor is electrically coupled to the frontside interconnect structure by way of a first source/drain contact,
wherein the source of the second pull-down transistor is electrically coupled to the backside interconnect structure by way of a first backside contact via.

11. The memory structure of claim 10, wherein the first memory cell further comprises:
a third gate structure extending lengthwise along the second direction and engaging the first active region to form a first pass-gate transistor; and
a fourth gate structure extending lengthwise along the second direction and engaging the fourth active region to form a second pass-gate transistor.

12. The memory structure of claim 11,
wherein the third gate structure is aligned with and spaced apart from the second gate structure along the second direction,
wherein the fourth gate structure is aligned with and spaced apart from the first gate structure along the second direction.

13. The memory structure of claim 10,
wherein the first active region and the fourth active region comprise a first width along the second direction,
where the second active region and the third active region comprise a second width along the second direction,
wherein the second width is smaller than the first width.

14. The memory structure of claim 10, further comprising:
a second memory cell comprising:
a fifth active region, a sixth active region, a seventh active region, and an eighth active region extending in parallel along the first direction,
a third gate structure extending lengthwise along the second direction to engage the fifth active region and the sixth active region to form a third pull-down transistor and a third pull-up transistor, respectively, and
a fourth gate structure extending lengthwise along the second direction to engage the seventh active region and the eighth active region to form a fourth pull-up transistor and a fourth pull-down transistor, respectively;
the frontside interconnect structure disposed over the second memory cell; and
the backside interconnect structure disposed below the second memory cell,
wherein a source of the third pull-down transistor is electrically coupled to the backside interconnect structure by way of a second backside contact via.

15. The memory structure of claim 14, wherein the fourth active region and the fifth active region are spaced apart by an isolation feature.

16. The memory structure of claim 15, wherein the first backside contact via and the second backside contact via merge below the isolation feature.

17. A semiconductor device, comprising:
a first pull-down transistor and a first pull-up transistor sharing a first gate structure extending along a direction;
a second pull-down transistor and a second pull-up transistor sharing a second gate structure extending along the direction;
a first pass-gate transistor having a third gate structure spaced apart but aligned with the second gate structure along the direction;
a second pass-gate transistor having a fourth gate structure spaced apart but aligned with the first gate structure along the direction;
a first backside butted contact physically contacting a bottom surface of the first gate structure and a bottom surface of a source of the second pull-up transistor; and
a second backside butted contact physically contacting the second gate structure and a source of the first pull-up transistor.

18. The semiconductor device of claim 17,
wherein the first pull-down transistor comprises a plurality of first nanostructures,
wherein the first gate structure wraps around each of the plurality of first nanostructures,
wherein the first pass-gate transistor comprises a plurality of second nanostructures,
wherein the third gate structure wraps around each of the plurality of second nanostructures,
wherein the plurality of first nanostructures comprise a first width along the direction,
wherein the plurality of second nanostructures comprise a second width along the direction,
wherein the first width is greater than the second width.

19. The semiconductor device of claim 18, wherein the plurality of first nanostructures comprise four (4) first nanostructures stacked one over another.

20. The semiconductor device of claim 17, further comprising:
a frontside interconnect structure disposed over the first pull-down transistor, the first pull-up transistor, the second pull-down transistor, the second pull-up transistor, the first pass-gate transistor, and the second pass-gate transistor, and
a backside interconnect structure disposed below the first pull-down transistor, the first pull-up transistor, the second pull-down transistor, the second pull-up transistor, the first pass-gate transistor, and the second pass-gate transistor,
wherein a source of the second pull-down transistor is electrically coupled to the frontside interconnect structure by way of a frontside source/drain contact,
wherein the source of the second pull-down transistor is electrically coupled to the backside interconnect structure by way of a backside contact via.
